(19) United States
(12) Patent Application Publication
(10) Pub. No.: US 2016/0100484 A1
(43) Pub. Date: Apr. 7, 2016

(54) PRINTED WIRING BOARD WITH BUMP AND METHOD FOR MANUFACTURING THE SAME

(71) Applicant: IBIDEN CO., LTD., Ogaki (JP)

(72) Inventors: Masatoshi KUNIEDA, Ogaki (JP); Katsuhiko TANNO, Ogaki (JP)

(73) Assignee: IBIDEN CO., LTD., Ogaki (JP)

(21) Appl. No.: 14/874,606

(22) Filed: Oct. 5, 2015

(30) Foreign Application Priority Data
Oct. 3, 2014 (JP) 2014-204503

(51) Int. Cl. H05K 1/11; H05K 3/40; H05K 1/09

(52) U.S. Cl. CPC H05K 1/111; H05K 1/09; H05K 3/4007

(57) ABSTRACT

A printed wiring board includes a base insulating layer including an insulating material, a conductor layer formed on the base insulating layer and including conductor pads, a coating insulating layer formed on the base insulating layer such that the coating insulating layer is covering the conductor layer and having opening portions exposing the conductor pads, respectively, and bumps formed on the conductor pads respectively such that each of the bumps includes an electroless plating metal layer formed on a respective one of the conductor pads and a solder layer formed on the electroless plating metal layer, the electroless plating metal layer having an upper end surface formed such that a central portion of the upper end surface is recessed relative to a peripheral portion of the upper end surface.

### CROSS-REFERENCE TO RELATED APPLICATIONS

The present application is based upon and claims the benefit of priority to Japanese Patent Application No. 2014-204503, filed Oct. 3, 2014, the entire contents of which are incorporated herein by reference.

### BACKGROUND OF THE INVENTION

1. Field of the Invention

The present invention relates to a printed wiring board with a bump and a method for manufacturing the same.

2. Description of Background Art

Japanese Patent Laid-Open Publication No. 2006-074002 describes a package substrate in which bumps as connecting parts between a package substrate and a semiconductor component are formed by mounting solder balls on conductor pads in openings of a solder resist layer as a coating insulating layer. The entire contents of this publication are incorporated herein by reference.

### SUMMARY OF THE INVENTION

According to one aspect of the present invention, a printed wiring board includes a base insulating layer including an insulating material, a conductor layer formed on the base insulating layer and including conductor pads, a coating insulating layer formed on the base insulating layer such that the coating insulating layer is covering the conductor layer and having opening portions exposing the conductor pads, respectively, and bumps formed on the conductor pads respectively such that each of the bumps includes an electroless plating metal layer formed on a respective one of the conductor pads and a solder layer formed on the electroless plating metal layer, the electroless plating metal layer having an upper end surface formed such that a central portion of the upper end surface is recessed relative to a peripheral portion of the upper end surface.

According to one aspect of the present invention, a method for manufacturing a printed wiring board includes preparing a printed wiring board including a base insulating layer including an insulating material, a conductor layer formed on the base insulating layer and including conductor pads, and a coating insulating layer formed on the base insulating layer such that the coating insulating layer is covering the conductor layer, forming opening portions penetrating through the coating insulating layer such that the opening portions reach the conductor pads, respectively, forming in each of the opening portions an electroless plating metal layer such that the electroless plating metal layer connects to a respective one of the conductor pads and has an upper end surface having a central portion which is recessed relative to a peripheral portion of the upper end surface, mounting solder only on the upper end surface of the electroless plating metal layer through an adhesive layer, and reflowing the solder by applying heat such that a solder layer is formed on the upper end surface of the electroless plating metal layer and a bump including the electroless plating metal layer and the solder layer protruding from a surface of the coating insulating layer is formed.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a printed wiring board with a bump according to an embodiment of the present invention;

FIG. 2A-2E are cross-sectional views illustrating a method for manufacturing a printed wiring board according to an embodiment of the present invention for manufacturing the printed wiring board illustrated in FIG. 1;

FIG. 3 is a cross-sectional view illustrating a printed wiring board with a bump according to another embodiment of the present invention;

FIG. 4 is a cross-sectional view illustrating a printed wiring board with a bump according to yet another embodiment of the present invention;

FIG. 5 is a cross-sectional view illustrating an applied example of a printed wiring board with a bump according to an embodiment of the present invention; and

FIG. 6 is a cross-sectional view illustrating another applied example of a printed wiring board with a bump according to an embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

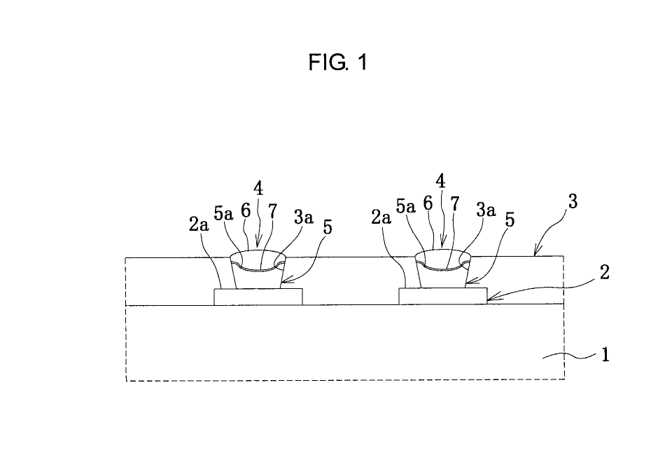

FIG. 1 is a cross-sectional view illustrating a printed wiring board with a bump according to an embodiment of the present invention. The printed wiring board with a bump of the embodiment includes: a base insulating layer 1 made of an insulating material; a conductor layer 2 that is formed on the base insulating layer and includes conductor pads (2a); a coating insulating layer 3 that is formed on the base insulating layer 1 and has openings (3a) that respectively expose the conductor pads (2a); and bumps 4 that are respectively formed on the conductor pads (2a) that are respectively exposed from the openings (3a). Each of the bumps 4 includes an electroless plating metal layer 5 that is formed on a conductor pads (2a) that is exposed from an openings (3a), and a solder layer 6 that is formed on the electroless plating metal layer 5 and protrudes from an upper surface of the coating insulating layer 3. A central part of an upper end surface of the electroless plating metal layer 5 is recessed relative to a peripheral part of the upper end surface. An alloy layer 7 is formed between the electroless plating metal layer 5 and the solder layer 6. The base insulating layer 1 may be a single-layer layer as illustrated in FIG. 1, and may also be a layer that has a structure in which layers are laminated and the conductor layer 2 is formed between insulating layers.

The insulating material that forms the base insulating layer 1 may be resin such as epoxy and may also be ceramic. The conductor layer 2 may be made of any conductive material and is preferably made of copper. A material that forms the coating insulating layer 3 may be ABF (Ajinomoto Build-up Film (trade name)), and may also be a normal solder resist. It is preferable that a pitch (center-to-center distance) of the bumps 4 be 30 μm or more and 80 μm or less. As a result, a package substrate can be formed on which, for example, mounted semiconductor components are connected by an ultrahigh density wiring. The electroless metal plating that forms the bumps 4 may be electroless copper plating. However, it is preferable that the electroless metal plating be electroless nickel plating. This is because the electroless nickel plating can be formed thicker than the electroless copper plating in a short period of time. The electroless copper plating or the electroless nickel plating is reliably filled in the openings (3a) of the coating insulating layer 3, the openings (3a) being finely formed along with a demand for fineness of the bump pitch. Therefore, the bumps 4 are likely to have uniform heights.

It is preferable that the conductor pads (2a) be SMD (Solder Mask Defined) type conductor pads. In the case of SMD type conductor pads, as illustrated in the drawings, the conductor pads (2a) are partially exposed from the openings (3a) of the coating insulating layer 3. The central part of the upper end surface of the electroless plating metal layer 5 that is formed on a conductor pad (2a) exposed from an openings (3a) is recessed relative to the peripheral part of the upper end surface. This is because the electroless plating metal is laminated from an inner peripheral surface of the opening (3a) and an exposed surface of the conductor pad (2a) toward the center of the opening.

When the electroless plating metal layer 5 is made of nickel, it is preferable that the solder layer 6 formed on the electroless plating metal layer 5 be formed of tin. This is because the alloy layer 7 is formed of an intermetallic compound of a nickel-tin alloy in which nickel and tin are tightly bonded.

It is preferable that phosphorus content in the electroless nickel plating that forms the electroless plating metal layer 5 be 5% or more and 12% or less. When the phosphorus content is less than 5%, it is likely to cause reduction in insulation due to migration. When the phosphorus content is more than 12%, adhesion strength of the solder bumps 6 (to be described later) decreases.

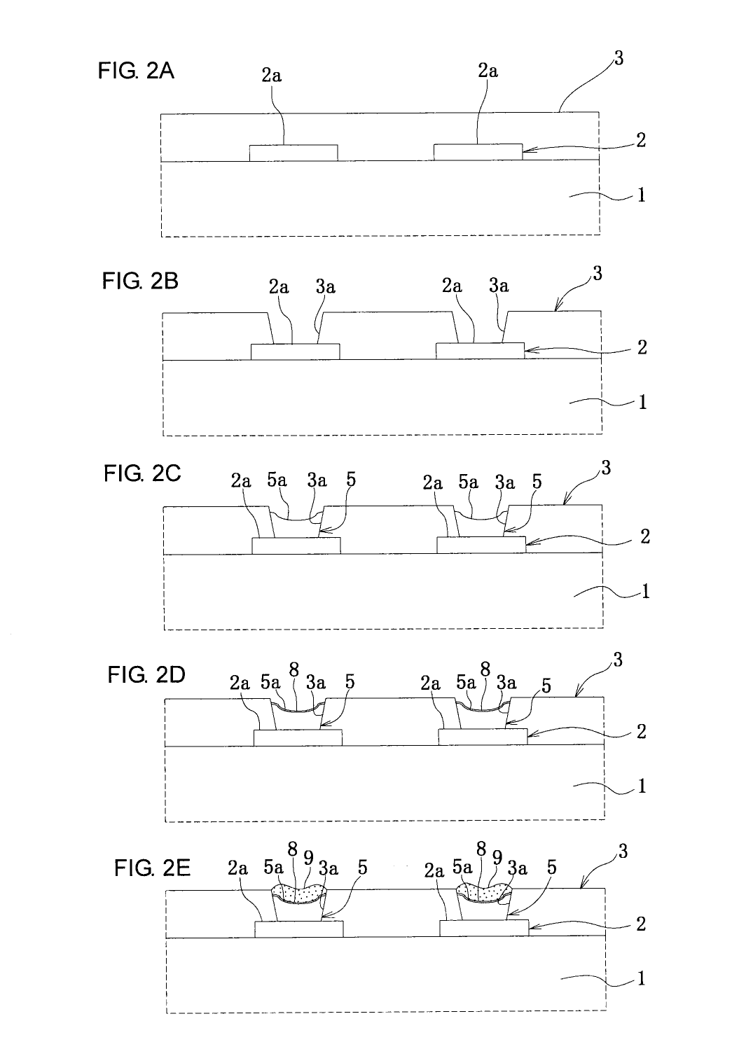

In the following, a method for manufacturing a printed wiring board with a bump according to an embodiment of the present invention is described based on the drawings. FIG. 2A-2E are cross-sectional views illustrating a method for manufacturing a printed wiring board with a bump according to an embodiment of the present invention.

In the method for manufacturing the printed wiring board of the present embodiment, as illustrated in FIG. 2A, an intermediate substrate is prepared that has the base insulating layer 1 and the conductor layer 2 formed on the base insulating layer 1, and the coating insulating layer 3 is formed on the base insulating layer 1 and the conductor layer 2. The base insulating layer 1 is formed of, for example, resin such as epoxy or ceramic. The conductor layer 2 is formed, for example, using an additive method, a semi-additive method, a subtractive method, or the like. The conductor layer 2 is formed of, for example, copper. The conductor layer 2 includes the conductor pads (2a) for mounting an electronic component such as a semiconductor component, and wirings (not illustrated in the drawings) such as a signal line and a power source line. The coating insulating layer 3 is formed of, for example, solder resist that is formed of insulating resin such as epoxy.

As illustrated in FIG. 2B, the openings (3a) that penetrate through the coating insulating layer 3 to reach the conductor pads (2a) are formed in the coating insulating layer 3. In the present embodiment, the openings (3a) are formed using laser, preferably UV laser that is suitable for forming small-diameter holes. By increasing laser output, the coating insulating layer 3 is sufficiently melted, and an inner wall surface of each opening (3a) is in an inverted truncated cone shape such that the inner wall surface linearly intersects the surface of the conductor pad (2a). By focusing a laser beam, the intersecting angle is set to 45 degrees or more and less than 90 degrees. An opening pitch (center-to-center distance) of the openings (3a) is preferably 30 μm or more and 80 μm or less. An opening diameter is preferably ½ of the opening pitch or less. For example, for an opening pitch of 55 μm, an opening diameter is 25 μm.

As illustrated in FIG. 2C, in each opening (3a) of the coating insulating layer 3, the electroless plating metal layer 5 is formed up to a vicinity of an upper surface of the coating insulating layer 3. The electroless plating metal layer 5 is formed, for example, by electroless nickel plating. The electroless plating metal layer 5 may also be formed by electroless copper plating.

The electroless plating metal is laminated from an inner peripheral surface of the opening (3a) and an exposed surface of the conductor pad (2a) toward the center of the opening. Therefore, the upper end surface (5a) of the electroless plating metal layer 5 is formed into a state in which the central part is recessed relative to the peripheral part that is adjacent to the inner peripheral surface of the opening (3a) of the coating insulating layer 3. At the time when the electroless plating metal layer 5 is formed up to the vicinity of the supper surface of the coating insulating layer 3, generation of the electroless plating metal is stopped.

As illustrated in FIG. 2D, an adhesive layer 8 is formed on the upper end surface (5a) of the electroless plating metal layer 5. The adhesive layer 8 is formed only on the upper end surface (5a) of the electroless plating metal layer 5 by applying, to the entire coating insulating layer 3, for example, a compound that exhibits adhesivity by reacting with the metal that forms the electroless plating metal layer 5, and thereafter removing the compound from the upper surface of the coating insulating layer 3 excluding the inside of the openings (3a) (for example, the SJ (Super Juffit) method of SHOWA DENKO K.K.: see Japanese Patent Laid-Open Publication No. HEI 10-51119). It is also possible that, instead of using the JS method, the adhesive layer 8 is formed only on the upper end surface (5a) of the electroless plating metal layer 5 by selectively supplying an adhesive into the openings (3a) using a mask or the like.

As illustrated in FIG. 2E, solder powder 9 made of, for example, tin powder is attached on the adhesive layer 8 on the upper end surface (5a) of the electroless plating metal layer 5 in each opening (3a) of the coating insulating layer 3. The solder powder 9 is attached only on the adhesive layer 8, for example, by spraying solder powder on the entire coating insulating layer 3 and thereafter removing the solder powder, by suction or the like, from the upper surface of the coating insulating layer 3 excluding the inside of the openings (3a).

Thereafter, by heating the substrate to reflow the solder powder 9, as illustrated in FIG. 1, the solder layer 6 that protrudes from the upper surface of the coating insulating layer 3 is formed only on the upper end surface (5a) of the electroless plating metal layer 5, and the alloy layer 7 made of an intermetallic compound (IMC) of the metal that forms the electroless plating metal layer 5 and the metal that forms the solder layer is formed between the upper end surface (5a) of the electroless plating metal layer 5 and the solder layer 6, and thereby the printed wiring board with a bump of the present embodiment is manufactured.

By adjusting an amount and a particle size of the solder powder 9, the solder layer 6 of any height can be formed. The height of the solder layer 6 is preferably 12-15 μm. By using nickel as the metal that forms the electroless plating metal layer 5 and using tin as the metal that forms the solder layer, the alloy layer 7 of a nickel-tin alloy can be formed, and the solder layer 6 can be firmly bonded to the electroless plating metal layer 5.

The central part of the upper end surface (5a) of the electroless plating metal layer 5 is recessed relative to the peripheral part of the upper end surface (5a). Therefore, the solder powder 9 is easily held in the openings (3a), and further, as compared to a case of a flat upper end surface, the upper end surface (5a) has a larger area and thus a bonding force between the solder layer 6 and the electroless plating metal layer 5 is increased.

According to the printed wiring board with a bump of the present embodiment and the method for manufacturing the printed wiring board, the electroless plating metal layer 5, the solder layer 6 and the alloy layer 7, which are made of conductors, are reliably formed in the openings (3a) of the coating insulating layer 3; bumps are each formed by the electroless plating metal layer 5, the solder layer 6 and the alloy layer 7; variation in heights of the bumps as connecting parts between a package substrate and a semiconductor component is reduced; and the pads (2a) can be reliably connected to bumps of the semiconductor component.

As a method forming the solder layer 6 and the alloy layer 7 on the upper end surface (5a) of the electroless plating metal layer 5, instead of the above-described SJ method in which the adhesive layer 8 and the solder powder 9 are used, the PPS (Precoated by Powder Sheet) method of Senju Metal Industry Co., Ltd. (see Japanese Patent Laid-Open Publication No. 2004-193334) may also be used. According to the PPS method, solder balls are held in holes, which are formed in a heat-resistant sheet and correspond to the openings (3a) of the coating insulating layer 3, by adhesive layers that are exposed to bottom surfaces and side surfaces of the holes; in a state in which the solder balls are opposed to the openings (3a) of the coating insulating layer 3, the heat-resistant sheet is put on the coating insulating layer 3 and is heated together with the printed board, and thereby, the solder balls are reflowed in the openings (3a); and thereafter, by removing the heat-resistant sheet, it is possible to form the solder layer 6 and the alloy layer 7 only on the upper end surface (5a) of the electroless plating metal layer 5.

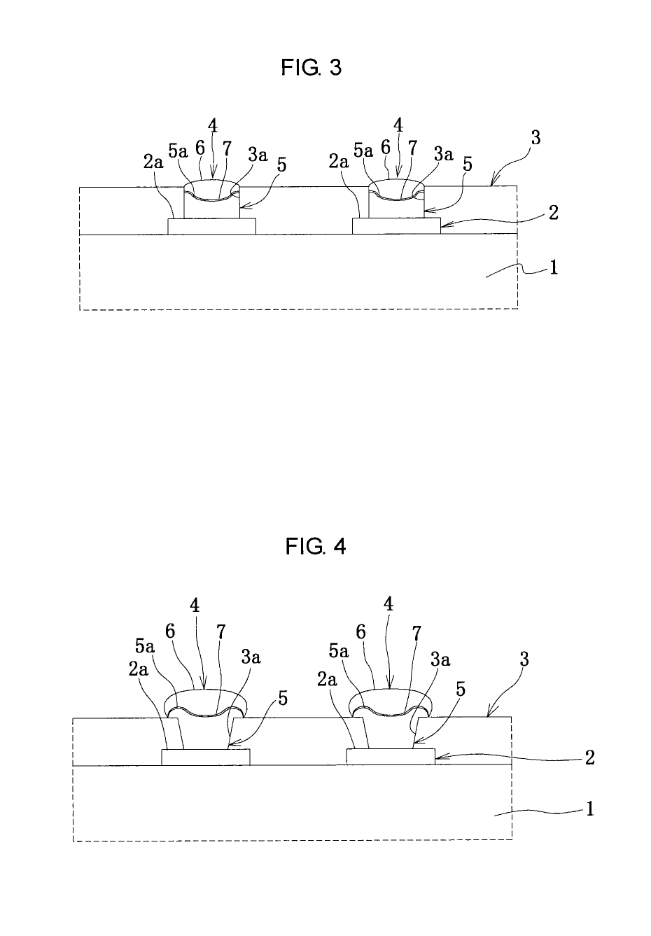

FIG. 3 is a cross-sectional view illustrating a printed wiring board with a bump according to another embodiment of the present invention. The printed wiring board with a bump of the present embodiment is different from the printed wiring board of the previous embodiment only in that the inner wall surface of an opening (3a) of the coating insulating layer 3 is in a cylindrical shape in which the inner wall surface of the opening (3a) is perpendicular to the surface of the conductor pad (2a), and has the same structure as the previous embodiment in other aspects. Hereinafter, solder resist is used as an example for the coating insulating layer 3. A manufacturing method of the present embodiment for manufacturing the printed wiring board is also different from the manufacturing method of the previous embodiment only in the method for forming the openings (3a) of the solder resist layer 3, and has the same structure as the previous embodiment in other aspects.

In the embodiment illustrated in FIG. 3, instead of laser, the openings (3a) of the solder resist layer 3 are formed by performing etching such as dry etching, plasma etching or light etching and thereafter performing an alkaline degreasing treatment. In this case, the inner wall surface of the opening (3a), and thus the side surface of the electroless plating metal layer 5 that is formed in close contact with the inner wall surface, is formed in a cylindrical shape in which the inner wall surface or the side surface is perpendicular to the surface of the conductor pad (2a).

FIG. 4 is a cross-sectional view illustrating a printed wiring board with a bump according to yet another embodiment of the present invention. The printed wiring board with a bump of the present embodiment is different from the printed wiring board of the previous embodiment only in that an upper end part of the electroless plating metal layer 5 protrudes from the opening (3a) of the solder resist layer 3 to a distance above the upper surface of the solder resist layer 3, is formed extending to an outer side of the opening (3a) to have an outer diameter larger than that of an end edge of the openings (3a) at the upper surface of the solder resist layer 3, and has a grommet-like shape in which the central part of the upper end surface (5a) is recessed relative to the peripheral part of the upper end surface (5a), and in that the solder layer 6 has an outer diameter larger than that of the end edge of the opening (3a) at the upper surface of the solder resist layer 3, and has the same structure as the previous embodiment in other aspects. A manufacturing method of the present embodiment for manufacturing the printed wiring board also has the same structure as the previous embodiment.

In the embodiment illustrated in FIG. 4, for example, by extending the electroless plating treatment time of the electroless plating metal layer 5, the electroless plating metal layer 5 is formed to protrude from the opening (3a) of the solder resist layer 3 to a distance above the upper surface of the solder resist layer 3. Also in this case, the central part of the upper end surface of the electroless plating metal layer 5 is recessed. On the upper end surface of the electroless plating metal layer 5, for example, by using the above-described SJ (Super Juffit) method, the solder powder is attached and, by reflowing the solder powder, the solder layer 6 and the alloy layer 7 are formed only on the upper end surface of the electroless plating metal layer 5. The upper end part of the electroless plating metal layer 5 has an outer diameter larger than that of the end edge of the opening (3a) at the upper surface of the solder resist layer 3. Therefore, the solder layer 6 and the alloy layer 7 also have an outer diameter larger than that of the end edge of the opening (3a) at the upper surface of the solder resist layer 3.

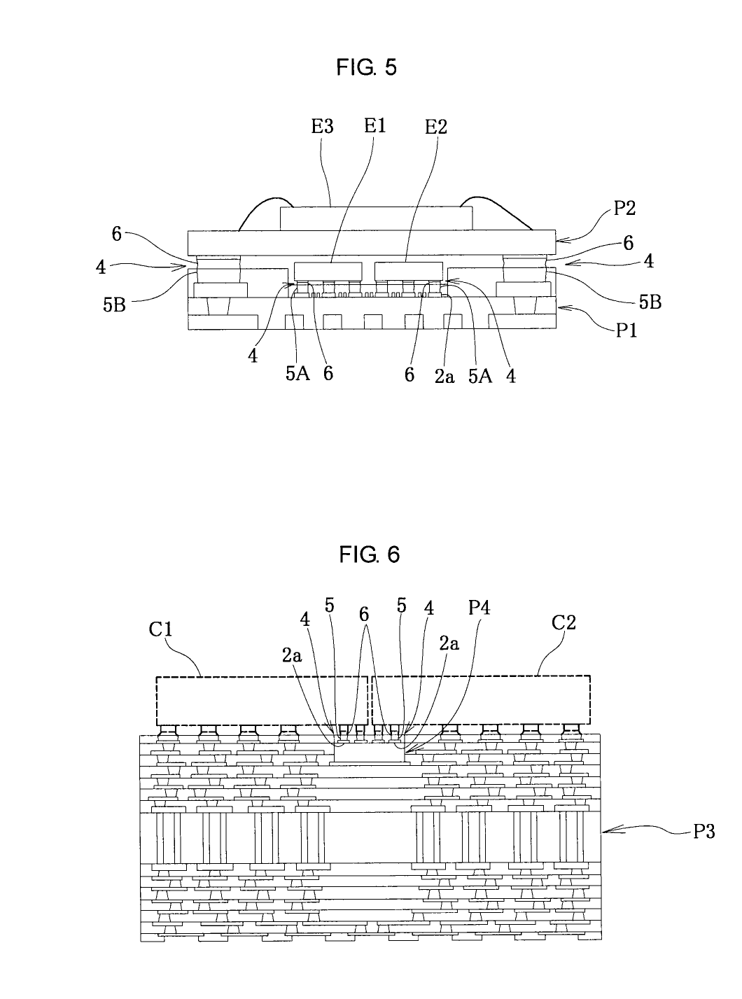

FIG. 5 is a cross-sectional view illustrating an applied example of a printed wiring board with a bump according to an embodiment of the present invention. In this application example, in a printed wiring board of a package on package (POP) type in which, on a lower side package substrate (P1) (on which semiconductor components (E1, E2) are mounted), an upper side package substrate (P2) (on which a semiconductor component (E3) is mounted) is laminated and is electrically connected, the printed wiring board with a bump of the embodiment that is manufactured in the same way as the previous embodiment is applied to the lower side package substrate (P1). The lower side package substrate (P1) is connected to terminals of the semiconductor components (E1, E2) via bumps 4 (that are formed based on an embodiment of the present invention on conductor pads (2a) in a central region of a pitch corresponding to a fine terminal pitch of the semiconductor components (E1, E2) and each have a small-diameter electroless plating metal layer (5A), an alloy layer (not illustrated in FIG. 5) on the small-diameter electroless plating metal layer (5A), and a solder layer 6), and is connected to terminals on a lower surface of the upper side package substrate (P2) via bumps 4 (that are formed based on an embodiment of the present invention on conductor pads (2a) in a peripheral region of a pitch corresponding to a large terminal pitch of the upper side package substrate (P2) and each have a large-diameter electroless plating metal layer (5B) having a height and a diameter larger than those of the small-diameter electroless plating metal layer (5A), an alloy layer (not illustrated in FIG. 5) on the large-diameter electroless plating metal layer (5B), and a solder layer 6).

When the lower side package substrate (P1) is manufactured, it is possible that openings of a coating insulating layer for the large-diameter electroless plating metal layers (5B), together with openings of a coating insulating layer for the small-diameter electroless plating metal layers (5A), are formed, for example, using the same UV laser, or are formed sequentially using different laser such as CO2 laser, and then the electroless plating metal layers (5A, 5B) are formed together or separately in the openings. Or, it is also possible that, after the openings of the coating insulating layer for the small-diameter electroless plating metal layers (5A) are formed, for example, using UV laser, in a state in which the openings of the coating insulating layer is covered by a PET film or the like, a coating insulating layer for the large-diameter electroless plating metal layers (5B) is formed, and openings are formed in the coating insulating layer by etching or the like, and, after the PET film or the like that covers the openings of the coating insulating layer for the small-diameter electroless plating metal layers (5A) is removed, the electroless plating metal layers (5A, 5B) are formed together or separately in the openings.

FIG. 6 is a cross-sectional view illustrating another application example of the printed wiring board with a bump of an embodiment of the present invention. In this application example, a printed wiring board (P4) with bumps of an embodiment manufactured in the same way as in the previous embodiment is embedded in a recess that is formed in two outer layers of a multilayer printed wiring board (P3). The printed wiring board (P4) connects, via bumps 4 (that are formed based on an embodiment of the present invention on conductor pads (2a) having pitches respectively corresponding to fine terminal pitches of, for example, a memory chip (C1) and a CPU chip (C2) as semiconductor components mounted on the multilayer printed wiring board (P3) and each have a small-diameter electroless plating metal layer 5, an alloy layer (not illustrated in FIG. 6) on the small-diameter electroless plating metal layer 5, and a solder layer 6), the terminals of the memory chip (C1) and the CPU chip (C2), and forms a wide band signal transmission line on/in a substrate (Wide Band Signaling on/in Substrate). It is also possible that the printed wiring board (P4) with bumps of the embodiment is mounted on an outer layer of the two layers of the multilayer printed wiring board (P3) and connects, for example, the memory chip (C1) and the CPU chip (C2).

Bumps as connecting parts between a package substrate and a semiconductor component may be formed by mounting solder balls on conductor pads in openings of a solder resist layer or by printing of solder paste. However, along with demand for a fine bump pitch, it has become difficult to reliably fill solders in openings of a solder resist layer.

Therefore, a bump connection method has been examined in which electroless tin plating having good solderability is filled in openings of a solder resist layer, and bumps formed by the electroless tin plating and bumps of a semiconductor component are connected by applying pressure to the bumps. However, the electroless tin plating requires processing for a longer period of time as compared to other electroless plating. In a case where a large number of substrates are processed for a long period of time in a batch in a rack system, due to variation in plating liquid exhaustion, a plating region may be non-uniform within a substrate. Therefore, variation in height of the plating is increased and it may cause a conduction failure when connecting to a semiconductor component.

A printed wiring board according to an embodiment of the present invention allows pads to be reliably connected to bumps of a semiconductor component by reliably forming conductors in openings of a coating insulating layer and reducing variation in heights of bumps as connecting parts between a package substrate and the semiconductor component.

A printed wiring board with a bump according to an embodiment of the present invention includes: a base insulating layer made of an insulating material; a conductor layer that is formed on the base insulating layer and includes a conductor pad; a coating insulating layer that is formed on the base insulating layer and has an opening that exposes the conductor pad; and a bump that is formed on the conductor pad. The bump includes: an electroless plating metal layer that is formed on the exposed conductor pad; and a solder layer that is formed on the electroless plating metal layer. A central part of an upper end surface of the electroless plating metal layer is recessed relative to a peripheral part of the upper end surface.

A method for manufacturing a printed wiring board with a bump according to an embodiment of the present invention includes: preparing a printed wiring board that includes a base insulating layer made of an insulating material, a conductor layer that is formed on the base insulating layer and includes a conductor pad, and a coating insulating layer that is formed on the base insulating layer and the conductor layer; forming an opening that penetrates the coating insulating layer to reach the conductor pad; forming, in the opening, an electroless plating metal layer that is electrically connected to the pad and of which a central part of an upper end surface is recessed relative to a peripheral part of the upper end surface; using an adhesive layer to mount solder only on the upper end surface of the electroless plating metal layer; and forming a solder layer that protrudes from an upper surface of the coating insulating layer on the upper end surface of the electroless plating metal layer by applying heat to the solder to reflow the solder and forming a bump that at least includes the electroless plating metal layer and the solder layer.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a base insulating layer comprising an insulating material;
a conductor layer formed on the base insulating layer and comprising a plurality of conductor pads;
a coating insulating layer formed on the base insulating layer such that the coating insulating layer is covering the conductor layer and having a plurality of opening portions exposing the plurality of conductor pads, respectively; and
a plurality of bumps formed on the plurality of conductor pads respectively such that each of the bumps comprises an electroless plating metal layer formed on a respective one of the conductor pads and a solder layer formed on the electroless plating metal layer, the electroless plating metal layer having an upper end surface formed such that a central portion of the upper end surface is recessed relative to a peripheral portion of the upper end surface.

2. A printed wiring board according to claim 1, wherein the electroless plating metal layer comprises an electroless nickel plating layer.

3. A printed wiring board according to claim 2, wherein the plurality of bumps is formed on the plurality of conductor pads respectively such that each of the bumps comprises an alloy layer interposed between the electroless plating metal layer and the solder layer.

4. A printed wiring board according to claim 1, wherein the coating insulating layer comprises a solder resist layer.

5. A printed wiring board according to claim 1, wherein the coating insulating layer comprises a resin film layer.

6. A printed wiring board according to claim 1, wherein the solder layer is formed on the electroless plating metal layer such that the solder layer is not extending over a surface of the coating insulating layer.

7. A printed wiring board according to claim 1, wherein the electroless plating metal layer has an upper end portion projecting with respect to a surface of the coating insulating layer such that the upper end portion has a diameter which is greater than an upper edge of a respective one of the opening portions, and the solder layer has a diameter which is greater than the upper edge of the respective one of the opening portions.

8. A printed wiring board according to claim 1, wherein the plurality of opening portions is formed in the coating insulating layer at a pitch such that each of the opening portions has a diameter which is one half of the pitch or less.

9. A printed wiring board according to claim 1, wherein the plurality of opening portions is formed in the coating insulating layer at a pitch in a range of 30 μm to 60 μm.

10. A printed wiring board according to claim 1, wherein the electroless plating metal layer is made of an electroless nickel plating layer.

11. A printed wiring board according to claim 10, wherein the plurality of bumps is formed on the plurality of conductor pads respectively such that each of the bumps comprises an alloy layer interposed between the electroless plating metal layer and the solder layer.

12. A printed wiring board according to claim 2, wherein the coating insulating layer comprises a solder resist layer.

13. A printed wiring board according to claim 2, wherein the coating insulating layer comprises a resin film layer.

14. A printed wiring board according to claim 2, wherein the solder layer is formed on the electroless plating metal layer such that the solder layer is not extending over a surface of the coating insulating layer.

15. A printed wiring board according to claim 2, wherein the electroless plating metal layer has an upper end portion projecting with respect to a surface of the coating insulating layer such that the upper end portion has a diameter which is greater than an upper edge of a respective one of the opening portions, and the solder layer has a diameter which is greater than the upper edge of the respective one of the opening portions.

16. A printed wiring board according to claim 2, wherein the plurality of opening portions is formed in the coating insulating layer at a pitch such that each of the opening portions has a diameter which is one half of the pitch or less.

17. A printed wiring board according to claim 2, wherein the plurality of opening portions is formed in the coating insulating layer at a pitch in a range of 30 μm to 60 μm.

18. A method for manufacturing a printed wiring board, comprising:
preparing a printed wiring board comprising a base insulating layer comprising an insulating material, a conductor layer formed on the base insulating layer and comprising a plurality of conductor pads, and a coating insulating layer formed on the base insulating layer such that the coating insulating layer is covering the conductor layer;
forming a plurality of opening portions penetrating through the coating insulating layer such that the plurality of opening portions reaches the plurality of conductor pads, respectively;
forming in each of the opening portions an electroless plating metal layer such that the electroless plating metal layer connects to a respective one of the conductor pads and has an upper end surface having a central portion which is recessed relative to a peripheral portion of the upper end surface;
mounting solder only on the upper end surface of the electroless plating metal layer through an adhesive layer; and
reflowing the solder by applying heat such that a solder layer is formed on the upper end surface of the electroless plating metal layer and a bump comprising the electroless plating metal layer and the solder layer protruding from a surface of the coating insulating layer is formed.

19. A method for manufacturing a printed wiring board according to claim 18, wherein the forming of the electroless plating metal layer comprises forming an electroless nickel plating layer.

20. A method for manufacturing a printed wiring board according to claim 19, wherein the reflowing of the solder comprises reflowing the solder such that an alloy layer is formed between the electroless nickel plating layer and the solder layer.
